(19) United States
(12) Patent Application Publication
(10) Pub. No.: US 2011/0252285 A1
(43) Pub. Date: Oct. 13, 2011

(54) Low Density Parity Check Encoding Method And Low Density Parity Check Encoder

(75) Inventor: Ganesansathish Kumar, Yongin-si (KR)

(73) Assignee: SAMSUNG ELECTRONICS CO., LTD., Suwon-si (KR)

(21) Appl. No.: 13/085,802

(22) Filed: Apr. 13, 2011

(30) Foreign Application Priority Data
Apr. 13, 2010 (KR) 1020100033712

(51) Int. Cl. H03M 13/11; G06F 11/10

(52) U.S. Cl. 714/752; 714/E11.032

(57) ABSTRACT

A low density parity check (LDPC) encoding method and an LDPC encoder are provided. The LDPC encoding method includes generating a H matrix and a He matrix. The H matrix includes a first section (H1) matrix and a second section (H2) matrix. The He is based on a ratio of the H matrix and a zero matrix to a C matrix and a D matrix. The method further includes generating a H1row matrix columnwise for each of a plurality of input vectors based on the H1 matrix and generating parity vectors for each of the plurality of input vectors based on the H1row matrix.

### CROSS-REFERENCE TO RELATED APPLICATION(S)

This application claims priority under 35 USC §119 to Korean Patent Application No. 2010-0033712, filed on Apr. 13, 2010, in the Korean Intellectual Property Office (KIPO), the contents of which are incorporated herein in its entirety by reference.

### BACKGROUND

1. Field

Example embodiments relate to an encoding method and an encoder in wireless communication system, and more particularly to a low density parity check (LDPC) encoding method and a LDPC encoder.

2. Description of the Related Art

Encoding is a process in which data is coded at a transmitting end to enable a receiving end to compensate for errors occurring from signal distortion and signal loss during data transmission. Therefore, the receiving end can recover the original data. Decoding is a process in which encoded data, from the transmitting end, is recovered as original data at the receiving end.

Low Density Parity Check (LDPC) code is a type of error-correcting code first described by Robert Gallager in his PhD thesis in 1962. In LDPC code a parity check matrix H, elements of which mostly correspond to ‘0’, is a low density linear block code. The LDPC codes were largely forgotten when first introduced because the LDPC codes include high complexity computations. However, recent advances in technology have renewed interest in the LDPC code.

The parity check matrix of the LDPC code has very few 1's in each row and column. Therefore, even in a large block, decoding is possible through a repetitive decoding procedure. If the size of the block becomes very large, the LDPC code nearly satisfies the known Shannon's channel capacity limit (e.g., in turbo coding).

The LDPC code can be defined by a (n−k)×n parity check matrix H, where ‘n’ denotes the size of a codeword after an encoding process and ‘k’ denotes the size of data bits before the encoding process. The generator matrix G can be derived from the following equation:

H·G=0. eq. 1

With respect to an encoding and decoding process using the LDPC code, the transmitting end uses the parity check matrix H and the generator matrix G for encoding data according to following equation:

c=G·u eq. 2

where, ‘c’ denotes a codeword, and ‘u’ denotes a data frame.

A process of encoding data using only the parity check matrix H and not the generator matrix G is being used. With respect to the encoding process using the LDPC code, the parity check matrix H may be considered as an important factor. Because the size of the parity check matrix H is approximately 1000×2000 or greater in practical communication systems, the process of encoding and decoding requires many calculations, complex expressions, and a large storage space.

### SUMMARY

Example embodiments provide a low density parity check (LDPC) encoding method being capable of reducing an amount of computation and latency.

Example embodiments provide a LDPC encoder being capable of reducing an amount of computation and latency.

According to example embodiments, a method of a low density parity check (LDPC) encoding includes generating a H matrix and a He matrix. The method further includes generating a H1row matrix columnwise for each of a plurality of input vectors based on the H1 matrix. The H matrix includes a first section (H1) matrix and a second section (H2) matrix. The He matrix is a

$$[ \begin{matrix}H & 0 \\ C & D\end{matrix} ]$$

matrix which is an extended version of H matrix. Parity vectors are generated for each of the plurality of input vectors based on the H1row matrix.

The H1 row matrix may be generated by shifting cyclically each of the input vectors by each of element values of the corresponding column of the H1 matrix

Each of column elements of the H1row matrix may be generated in parallel. The column elements are involved with the plurality of input vectors.

The parity vectors may be generated sequentially after calculating all of the columns of the H1row matrix.

In at least one example embodiment, the generated parity vectors and the input vectors may be transmitted as codewords.

In at least one example embodiment, a first part of a Crow matrix may be generated for each of the input vectors based on the C matrix, simultaneously with the generation of the H1row matrix. A second part of the Crow matrix may be generated for each of the input vectors based on the C matrix. Extended parity vectors may be generated based on the Crow matrix.

In at least one example embodiment when a code rate is ½, the H1 matrix may be H1=[0 0 0 0 21 0 0 24 0 1 0 0 0 0 0 0 0 4 0 0; 0 0 20 19 0 18 0 0 0 0 0 0 0 14 0 0 0 0 0 0; 0 0 0 0 23 14 20 0 0 0 0 0 0 0 0 0 0 0 13 0; 4 0 0 0 0 0 0 14 0 0 0 0 0 0 0 0 29 17 0 0; 0 0 4 11 0 0 0 0 2 0 0 0 0 12 0 0 0 0 0 0; 0 0 0 0 9 0 0 0 0 0 0 0 0 0 0 11 0 11 14 0; 0 0 0 0 0 0 0 0 0 13 0 14 0 7 0 0 20 0 0 0; 0 0 0 0 6 0 28 0 9 0 0 25 0 0 0 0 0 0 0 0; 0 0 0 0 0 24 0 0 0 0 0 0 0 0 0 15 0 0 15 23; 0 3 0 0 0 0 16 29 0 0 0 0 0 0 0 0 0 0 0 0; 0 0 0 14 0 0 0 0 18 0 0 0 0 0 0 0 0 0 0 19; 0 0 0 0 0 0 0 0 0 2 0 0 2 2 21 0 0 0 0 0; 0 7 0 0 0 0 0 0 0 0 0 1 23 0 0 0 22 0 0 0; 0 0 0 0 0 0 0 0 0 0 0 26 26 0 11 0 0 0 0 4; 8 0 11 0 0 0 0 0 0 0 0 0 0 0 0 8 0 0 0 0; 0 20 5 3 0 0 0 0 0 0 0 0 0 0 0 0 0 0 0 18; 15 0 0 0 0 0 0 0 27 0 17 0 0 0 17 0 0 0 0 0; 0 0 0 0 0 4 0 0 0 18 25 0 0 0 0 0 0 0 0 22 0; 0 24 0 0 0 0 0 0 0 0 0 0 16 0 16 0 0 0 0 0; 0 0 0 0 0 0 0 7 0 0 20 0 0 0 0 26 0 5 0 0].

The H2 matrix may be H21=h2(f)|H2′]. The h2(f) is first column of the H2 matrix. The ‘f’ is from 0 to 19, the h2(0) is 2, the h2(9) is 1, the h2(19) is 2, and the H2′ has a dual diagonal structure (elements of the H2′ are 1 if i=j, or j=i+1, and are 0 otherwise, the ‘i’ being row index of the H2′ (i is from 0 to 19), the ‘j’ being column index of the H2′ (j is from 1 to 19)).

The C matrix may be C=[0 0 0 0 0 0 13 0 0 0 0 20 0 0 0 0 1 0 0 0 0 0 0 0 0 0 0 21 0 0 0 0 0 0 0 0 0 0 0 0; 0 0 0 0 0 0 0 0 0 12 0 0 0 0 0 0 0 0 0 10 0 0 0 19 0 0 0 0 0 0 0 0 0 0 0 0 0 0 0 0; 0 0 2 0 0 0 0 0 0 0 0 0 0 0 0 3 0 0 0 0 5 0 0 0 0 10 0 0 0 0 0 0 0 0 0 0 0 0 0 0; 19 0 0 0 0 0 0 0 16 0 0 0 26 0 3 0 0 0 0 0 0 0 0 0 0 0 0 0 0 0 0 0 0 0 0 0 0 0 0 0]. The ‘0’ is a zero matrix. The D matrix may be D=[2 1 0 0; 1 1 1 0; 0 0 1 1; 2 0 0 1]. The code rate is a ratio of each length of the input vectors to each length of code words. The code word includes the input vectors and the parity vectors.

In at least one example embodiment when a code rate is ⅝, The H1 matrix may be H1=[0 0 0 0 13 0 0 0 0 18 11 0 14 0 9 0 0 0 20 0 0 0 0 22 0; 0 0 0 0 0 20 24 4 24 0 8 0 0 0 0 0 0 0 6 0 0 0 0 0 0; 0 0 0 0 0 0 0 0 0 0 0 0 0 23 0 0 0 1 11 29 17 27 0 0 0; 0 0 7 18 0 0 0 21 0 0 0 22 0 0 0 29 0 0 0 1 0 26 0 0 0; 0 0 19 1 0 0 0 0 0 0 0 0 0 0 22 0 24 0 0 0 0 0 15 0 6; 26 3 8 0 0 16 9 0 0 0 0 0 0 0 28 0 0 0 0 0 0 0 0 0 0; 4 0 0 0 0 12 22 0 18 0 0 0 9 7 0 0 27 0 0 0 0 0 0 0 0; 0 12 0 0 1 0 0 0 0 0 0 0 21 0 0 17 0 0 0 0 4 0 0 4 0; 0 0 0 8 0 0 0 0 28 0 8 21 0 0 0 4 0 0 0 0 0 0 12 0 0; 0 0 0 0 0 0 0 0 0 7 26 0 0 0 23 0 0 0 0 0 0 0 9 3 28; 9 0 0 0 0 0 0 30 29 0 0 0 0 10 0 0 0 17 0 0 0 4 0 0 0; 0 0 0 0 8 0 0 0 0 0 0 0 8 0 0 0 12 0 0 0 2 0 0 14 12; 0 0 6 20 17 0 0 2 0 0 0 17 0 0 0 26 0 0 0 0 0 0 0 0 0; 0 6 0 0 0 30 30 0 0 0 0 0 0 0 0 0 24 0 0 0 24 0 16 0 0; 0 0 0 0 0 0 0 0 0 6 0 30 0 5 0 0 0 27 0 21 01 0 0 0].

The H2 matrix may be H2=[h₂(f)|H2′]. The h₂(f) is first column of the H2 matrix. The ‘f’ is from 0 to 14, the h₂(0) is 2, the h₂(7) is 1, the h₂(14) is 2, and the H2′ has a dual diagonal structure (elements of the H2′ are 1's if i=j, or j=i+1, and are 0 otherwise, the ‘i’ being row index of the H2′ (i is from 0 to 14), the ‘j’ being column index of the H2′ (j is from 1 to 14)).

The C matrix may be C=[0 0 0 0 0 0 0 0 0 0 0 0 0 0 0 0 0 8 0 0 0 0 0 0 9 0 0 0 0 0 26 0 2 25 14 0 0 6 0 0; 0 0 0 0 0 0 0 0 0 0 0 0 0 0 0 0 20 0 0 0 0 0 0 0 0 9 15 0 0 29 13 0 0 29 0 0 0 0 0 0; 18 0 0 0 0 22 0 17 0 0 0 0 0 0 0 0 0 0 22 0 2 10 0 0 0 0 0 0 0 0 0 0; 0 0 0 0 0 0 0 0 0 8 0 29 0 0 0 0 0 0 17 4 0 0 0 0 0 0 0 0 0 0 0 0 0 0 0 0 0 0 19 17].

The ‘0’ is a zero matrix. The D matrix may be D=[2 1 0 0; 1 1 1 0; 0 0 1 1; 2 0 0 1]. The code rate is a ratio of each length of the input vectors to each length of code words. The code word includes the input vectors and the parity vectors.

In at least one example embodiment when a code rate is ¾, the H1 matrix may be H1=[2 0 0 0 0 0 0 0 0 29 6 0 0 0 0 0 28 3 28 8 0 0 0 12 20 0 0 0 20; 7 0 0 0 7 9 0 16 0 5 0 0 24 0 0 0 0 17 0 0 0 27 0 0 0 0 0 0 8 3; 0 22 0 23 11 22 0 0 25 12 0 0 0 0 0 0 21 0 0 0 0 0 0 0 0 0 16 2 22 0; 0 25 7 0 0 0 1 0 14 0 0 0 0 0 27 16 23 0 27 0 0 0 0 27 0 30 0 0 0 0; 0 19 0 3 0 12 0 0 30 0 0 0 0 0 0 28 0 0 28 0 0 0 28 0 0 22 0 0 0 29; 0 0 9 0 0 0 0 4 0 0 0 0 22 21 4 9 29 0 0 0 0 0 7 14 0 0 0 15 0 0; 24 0 0 0 0 0 0 0 0 0 12 25 28 29 30 0 0 0 0 18 20 13 0 11 0 0 0 0 0 0; 0 29 0 0 0 4 6 0 25 6 0 0 0 0 0 0 0 0 0 11 0 29 0 0 5 0 12 0 7 0; 0 0 28 0 0 0 28 0 0 0 10 0 0 28 0 0 10 0 0 14 2 0 0 0 22 0 14 8 0 0; 0 0 0 7 19 0 0 22 0 0 6 4 0 0 0 0 0 7 0 0 5 0 20 0 0 0 0 5 0 8]. The H2 matrix may be H2=[h₂(f)|H2′].

The h₂(f) is a first column of the H2 matrix. The ‘f’ is from 0 to 9, the h₂(0) is 2, the h₂(4) is 1, the h₂(9) is 2, and the H2′ has a dual diagonal structure (elements of the H2′ are 1's if i=j, or j=i+1, and are 0 otherwise, the ‘i’ being row index of the H2′ (i is from 0 to 9), the ‘j’ being column index of the H2′ (j is from 1 to 9)).

The C matrix may be C=[0 0 0 9 0 0 0 0 0 0 0 27 0 0 12 0 0 0 0 0 0 0 21 0 0 0 0 0 0 0 0 0 0 14 0 0 17 22 0 0; 27 0 0 0 0 0 0 0 0 0 0 0 15 21 0 0 0 0 18 0 0 0 0 0 0 24 0 0 0 0 0 18 12 0 0 11 0 0 0 0; 0 0 0 0 0 0 20 0 0 0 0 0 0 0 0 0 0 0 0 0 0 0 0 0 0 0 0 0 0 0 0 0 4 26 30 0 0 0 0 17; 0 0 0 0 8 0 0 0 0 1 0 0 0 0 0 0 0 11 0 0 0 0 0 0 12 0 0 0 13 0 0 0 0 0 0 0 0 0 12 0]. The ‘0’ is a zero matrix. The D matrix may be D=[2 1 0 0; 1 1 1 0; 0 0 1 1; 2 0 0 1]. The code rate is a ratio of each length of the input vectors to each length of code words. The code word includes the input vectors and the parity vectors.

In at least one example embodiment when a code rate is ⅘, the H1 matrix may be H1=[0 0 0 23 0 0 0 0 12 25 12 24 0 0 0 0 23 0 0 0 3 13 0 13 0 28 0 15 11 0 0 29; 0 0 21 0 0 14 0 25 0 0 0 14 0 0 14 14 27 0 0 1 0 19 7 0 28 0 0 0 0 8 8 0; 19 0 16 0 0 5 0 18 0 0 0 0 62 0 17 0 0 14 20 0 0 25 0 13 0 4 0 0 6 0 0; 24 1 0 20 29 0 30 0 14 0 28 0 0 0 0 0 0 2 20 0 0 0 0 17 0 0 0 0 22 0 0 6; 15 11 11 0 23 27 14 0 0 0 0 0 0 9 15 0 0 30 0 0 0 0 13 0 2 0 27 0 0 0 7 0; 0 0 10 0 0 0 0 20 0 14 0 22 9 14 0 28 0 0 0 17 0 0 0 0 19 19 8 2 0 15 0 0; 0 0 0 0 0 0 0 0 23 18 20 23 0 0 0 0 0 13 0 13 0 0 0 0 13 0 3 2 0 0 3; 0 19 0 9 6 0 20 0 0 0 19 0 0 0 27 0 24 17 0 0 12 9 0 12 0 0 0 0 6 0 10 0]. The H2 matrix may be H2=[h₂(f)|H2′].

The h₂(f) is a first column of the H2 matrix. The ‘f’ is from 0 to 7, the h₂(0) is 2, the h₂(3) is 1, the h₂(7) is 2, and the H2′ has a dual diagonal structure (elements of the H2′ are 1's if i=j, or j=i+1, and are 0 otherwise, the i′ being row index of the H2′ (i is from 0 to 7), the ‘j’ being column index of the H2′ (j is from 1 to 7)).

The C matrix may be C=[0 0 11 14 0 0 0 0 0 0 0 0 29 0 0 0 0 0 0 0 0 0 4 0 0 1 3 0 0 0 0 0 2 0 0 11 28 25 0 0; 0 0 0 0 0 25 0 0 0 0 0 0 0 0 0 0 20 0 0 0 0 23 0 0 0 0 0 0 0 0 0 0 19 23 0 0 0 0 2; 0 0 0 0 0 0 0 0 28 0 0 0 0 0 0 0 0 0 0 0 0 0 0 0 0 0 0 0 0 0 0 0 0 1 0 0 3 8 5 0; 0 0 0 0 0 0 0 1 0 0 0 0 0 0 0 6 0 0 19 16 0 0 0 0 0 0 0 0 0 6 0 0 0 0 18 7 0 0 17 9]. The ‘0’ is a zero matrix. The D matrix may be D=[2 1 0 0; 1 1 1 0; 0 0 1 1; 2 0 0 1]. The code rate is a ratio of each length of the input vectors to each length of code words. The code word includes the input vectors and the parity vectors.

According to example embodiments, a low density parity check (LDCP) encoder includes a table unit, an arithmetic unit, and a controller. The table unit stores a H matrix and a

$$He = [ \begin{matrix}H & 0 \\ C & D\end{matrix} ]$$

matrix. The H matrix includes a first section (H1) matrix and a second section (H2) matrix. The He matrix is an extended version of the H1 matrix. The arithmetic unit is configured to generate a H1row matrix columnwise for each of a plurality of input vectors based on the H1 matrix, and to generate parity vectors for each of the plurality of input vectors based on the H1 row matrix. The controller is configured to control the table unit and the arithmetic unit.

In at least one example embodiment, the controller may include barrel shifters and a parity generating unit. The barrel shifters may generate the H1 row matrix by shifting cyclically each of the input vectors by each of element values of the corresponding column of the H1 matrix. The parity generating unit may store the generated H1 row matrix, and generate the parity vectors based on the H1 row matrix.

The barrel shifters may generate each of column elements of the H1 row matrix in parallel. The column elements may be involved with the plurality of input vectors.

In at least one example embodiment, the LDPC encoder may generate C row matrix columnwise for each of the input vectors and for the parity vectors based on the C matrix. The LDPC encoder may further generate extended parity vectors based on the generated C row matrix.

According to example embodiments, a wireless communication system may include a transmitter having the LDPC encoder.

According to example embodiments, a method of a low density parity check (LDPC) encoding includes shifting each of a plurality of input vectors by each value of an element of a corresponding column of a first matrix and generating parity vectors for each of the plurality of input vectors based on the shifted input vectors.

In at least one example embodiment, the LDPC encoding method may further include transmitting the generated parity vectors and the input vectors as a plurality of codewords.

In at least one example embodiment, a variable code rate of transmission data may be based on a ratio of a length of the input vectors to a length of the plurality of codewords. The variable code rate of transmission data may vary based on matrices associated with a second matrix.

In at least one example embodiment, the LDPC encoding method may further include generating a first part and a second part of a row matrix. The first part and the second part of the row matrix may be generated for each of the input vectors based on a second matrix. The LDPC encoding method may further include generating extended parity vectors based on the row matrix. The first part of the row matrix may be generated in parallel with the shifting of each of the plurality of input vectors.

### BRIEF DESCRIPTION OF THE DRAWINGS

Illustrative, non-limiting example embodiments will be more clearly understood from the following detailed description taken in conjunction with the accompanying drawings. FIGS. 1-10 represent non-limiting, example embodiments as described herein.

FIG. 1 is a block diagram illustrating a wireless communication system according to example embodiments.

FIG. 2 is a block diagram illustrating a configuration of an LDPC encoder in FIG. 1.

FIG. 3 is a diagram illustrating He matrix when a code rate is ½.

FIG. 4 is a diagram illustrating He matrix when a code rate is ⅝.

FIG. 5 is a diagram illustrating He matrix when a code rate is ¾.

FIG. 6 is a diagram illustrating He matrix when a code rate is ⅘.

FIG. 7 is a timing diagram illustrating process of generating parity vectors.

FIG. 8 is a timing diagram illustrating process of generating extended parity vectors.

FIG. 9 is a flow chart illustrating the LDPC encoding method according to some example embodiments.

FIG. 10 is a flow chart illustrating the LDPC encoding method according to other example embodiments.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Various example embodiments will be described more fully hereinafter with reference to the accompanying drawings, in which some example embodiments are shown. Example embodiments of the inventive concept may, however, be embodied in many different forms and should not be construed as limited to the example embodiments set forth herein. Rather, these example embodiments are provided so that this disclosure will be thorough and complete, and will fully convey the scope of the present inventive concept to those skilled in the art. In the drawings, the sizes and relative sizes of layers and regions may be exaggerated for clarity. Like numerals refer to like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

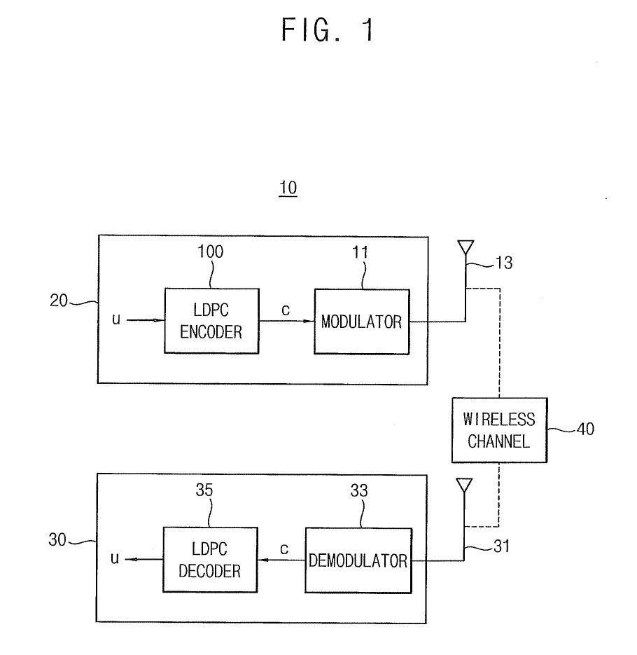

FIG. 1 is a block diagram illustrating a wireless communication system according to at least one example embodiment.

Referring to FIG. 1, a wireless communication system 10 may include a transmitter 20 and a receiver 30. The transmitter 20 may include a low density parity check (LDPC) encoder 100 and a modulator 11. The receiver 30 may include a demodulator 33 and a LDPC decoder 35. The transmitter 20 and the receiver 30 may perform communication via a wireless channel 40. In the transmitter 20, source data u may be converted to a codeword c using an encoding process by the LDPC encoder 100. The modulator 11 may perform wireless-modulation of the codeword c to transmit the codeword c via an antenna 13.

An antenna 31 of the receiver may receive a signal transmitted through the wireless channel 40, and the receiver 30 may perform the process which is performed by the transmitter 20 in reverse order. In other words, the demodulator 33 may demodulate the received signal to the codeword c, and the LDPC decoder 35 may convert the codeword c to the source data u.

The data communicating process described above is outlined briefly to simply explain features of example embodiments. Therefore, example embodiments are not limited to the above process and other processes for data communication are also considered.

A transmitter (e.g., transmitter 20) may determine a code rate CR by considering channel conditions and an amount of transmission data. Equation 3 is a formula for obtaining the code rate CR.

CR=k/n eq. 3

where, ‘k’ denotes a length of the source data, and ‘n’ denotes a length of codeword ‘c’, which is an encoded data. A plurality of input vectors may be entered as the source data ‘u’, and ‘k’ denotes each length of the input vectors.

The encoded data (e.g., codeword c) may have two sections. A first section may be system bits which indicate the source data before encoding. A second section may be parity bits which are added to the system bits after encoding. The number of the system bits and the number of the parity bits indicate codeword length ‘n’.

In the LDPC encoding method according to example embodiments, the input source data may be encoded through equation 1 and equation 2, by using a generator matrix G. An input source data s_{1×k} having k-bits is encoded to a codeword x_{1×n} having n-bits. The codeword x may have a structure of x=[s p]=[s₀, s₁, . . . , sₖ₋₁, p₀, p₁, . . . , pₙ₋ₖ₋₁]. Here, (s₀, s₁, . . . , sₖ₋₁) denotes the system bits, and (p₀, p₁, . . . , pₙ₋ₖ₋₁) denotes the parity bits. Further, x is the codeword c expressed in vector form, and s is the source data u expressed in vector form.

However, to encode using the generator matrix G may be relatively complex. Therefore, directly encoding the input source data using a parity check matrix H instead of the generator matrix G may be relatively less complex. In other words, relationship H·x=H·[s p]=0 may be derived from the relationship H·x=0 because x=[s p]. Therefore, parity check bit ‘p’ may be obtained, and the codeword x=[s p] may be obtained.

The receiver 30 in FIG. 1 may receive the encoded data, which is encoded as described above. The receiver 30 may decode the encoded data according to following equation:

H·x^{T}=0^{T} eq. 4

Decoding errors may be determined using equation 4. In other words, there may be no errors if the product of the encoded data x and the parity check matrix H is zero. In addition, there may be errors if the product of the encoded data x and the parity check matrix H is not zero. Therefore, the source data (e.g., source data 4) may be extracted.

In equation 1, the parity check matrix H may be expressed H=[H1|H2]. Here, a dimension of H1 may be (n−k)×k, and a dimension of H2 may be (n−k)×(n−k). In addition, H2=[h₂(f)|H2′]. h₂(f) may be a first column of the H2 matrix, and ‘f’ is from 0 to n−k. h₂(f) may include h₂(0)=1, h₂(integer part of ‘n−k/2’)=1, h₂(n−k)=1, and other elements of h₂(f) may be 0's. The H2′ may have a dual diagonal structure, where the elements of H2′ are 1 if i=j or j=i+1, and other elements of H2′ are 0. ‘i’ is a row index of H2′ (i is from 0 to n−k) and ‘j’ is a column index of H2′ (j is from 0 to n−k).

Therefore, equations (shown below) may be obtained by using equation 4 and the relationship H=[H1|H2] and x=[s p].

p^{T}=H2⁻¹·H1·s^{T} eq. 5

where, H2=[h₂(f)|H2′] and the H2′ has the diagonal structure. Therefore, the H2⁻¹ can be obtained relatively easily.

If p={P₀, P₁, . . . , Pₘ} (m=n−k) and s={S₀, S₁, . . . , Sₖ₋₁}, equation 6 (shown below) may be obtained.

$${P}_{0}^{T} = {\sum }_{e = 0}^{m - 1} H 1 row ( e ) \cdot {s}^{T} \\ {P}_{1}^{T} = H 1 row ( 0 ) \cdot {s}^{T} + {h}_{0} \cdot {P}_{0}^{T} \\ {P}_{2}^{T} = H 1 row ( 1 ) \cdot {s}^{T} + {h}_{1} \cdot {P}_{0}^{T} + {P}_{1}^{T} \\ … \\ {P}_{m - 1}^{T} = H 1 row ( m - 2 ) \cdot {s}^{T} + {h}_{m - 2} \cdot {P}_{0}^{T} + {P}_{m - 2}^{T} . \qquad eq . 6$$

Where, P₀, P₁, . . . , Pₘ denote parity vectors, each of the parity vectors having m bits. S₀, S₁, . . . , Sₖ₋₁ denote the input vectors, each of the input vectors having n−k bits. The source data in FIG. 1 may be one of the S₀, S₁, . . . , Sₖ₋₁. H1 row(e) matrices may be obtained by cyclically shifting with values of column elements of the H1 matrix, for each of the input vectors S₀, S₁, . . . , Sₖ₋₁.

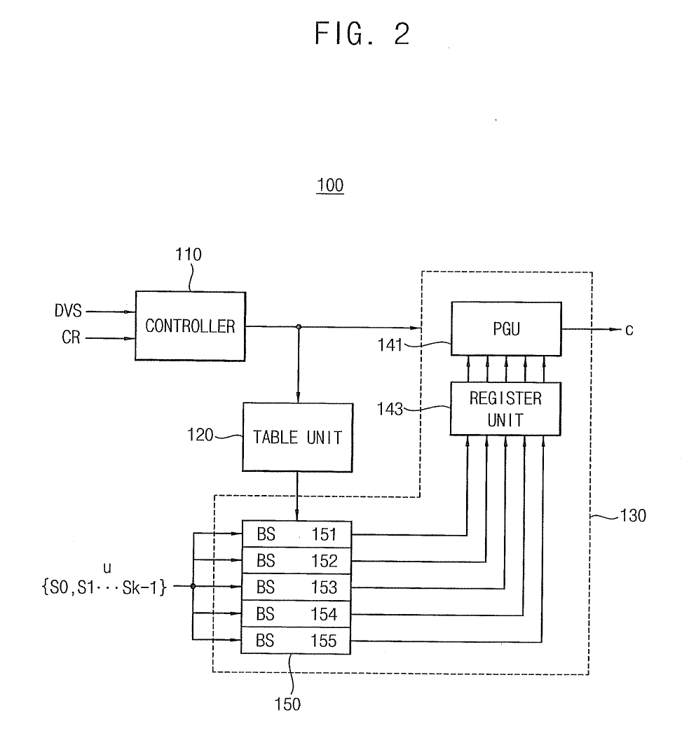

FIG. 2 is a block diagram illustrating a configuration of an LDPC encoder in FIG. 1 according to example embodiments.

Referring FIG. 2, the LDPC encoder 100 may include a controller 110, a table unit 120, and an arithmetic unit 130. The arithmetic unit 130 may include a shifter unit 150, a register unit 143, and a parity generating unit (PGU) 141. The shifter unit 150 may include a plurality of barrel shifters (BS) 151 to 155.

The table unit 120 stores a H matrix and a C matrix, which are included in a

$$He = [ \begin{matrix}H & 0 \\ C & D\end{matrix} ]$$

matrix. The He matrices are a variety of extended versions of H matrices according to the various code rates. In addition, H=[H1|H2] and H2=[h₂(f)|H2′], as described above.

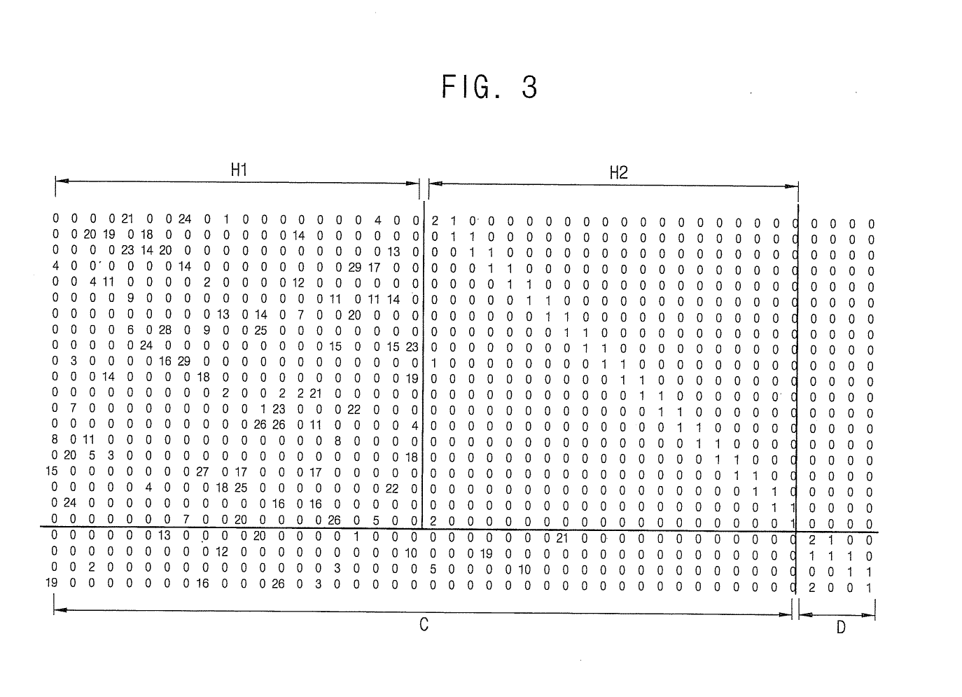

FIGS. 3 to 6 illustrate the various He matrices according to the code rates according to at least one example embodiment.

The controller 110 provides the various element values of the H matrix and the C matrix, according to the code rate CR.

Referring to FIGS. 3 to 6, a majority of the elements of the H matrix and C matrix are ‘0’. Therefore, when H1row(e) matrix is calculated according to equation 6, calculation time may be reduced because the calculation is performed only with the non-zero elements.

A process of generating the parity vectors P₀, P₁, . . . , Pₘ using the H matrix is described below.

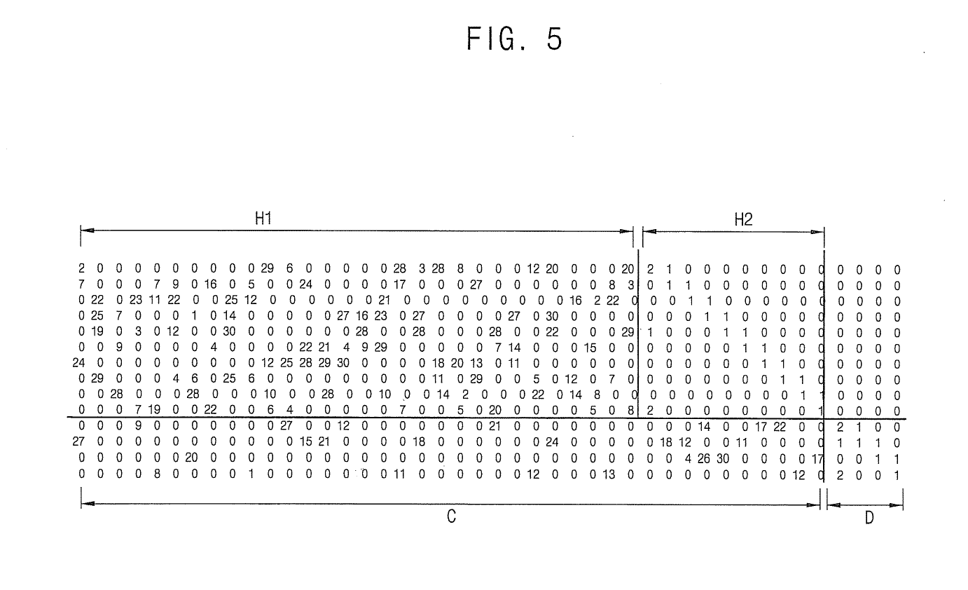

Referring to FIG. 2, the shifter unit 150 may cyclically shift the input vectors S₀, S₁, . . . , Sₖ₋₁ with non-zero element values of the corresponding column of the H1 matrix to store the input vectors in the register unit 143. For example, the He matrix with the code rate of ¾ represented in FIG. 5. For example, each of the S₀, S₁, . . . , Sₖ₋₁ may include 30 bits. When S₀ is entered as an input, the shifter unit 150 cyclically shifts S₀ with values of 2, 7, and 24, which are the non-zero elements of the first column of the H1 matrix. Further, the shifted S₀ is stored in the register unit 143, as a corresponding element of the H1row(e) matrix. The process described above is repeated until Sₖ₋₁ is entered. In other words, when Sₖ₋₁ is entered (k=30), the shifter unit 150 cyclically shifts Sₖ₋₁ with values 20, 3, 29, and 8, which are the non-zero elements of the last column of the H1 matrix. Further, the shifter unit 150 stores Sₖ₋₁ as a corresponding element of the H1row(e) matrix, in register unit 143.

In other words, the barrel shifters 151 to 155 of the shifter unit 150 ignore the zero-element of the H1 matrix. If an element of the H1 matrix is zero, a corresponding element of the H1row(e) matrix is also zero. In other words, the input vectors S₀, S₁, . . . , Sₖ₋₁ are cyclically shifted columnwise with non-zero elements of the each column of the H1 matrix. The shifted input vectors S₀, S₁, . . . , Sₖ₋₁ are stored in the register unit 143 as corresponding elements of the H1row(e) matrix. In other words, when S₀ is entered, the first column elements of the H1row(e) matrix are generated and stored in the register unit 143. When S₁ is entered, the second column elements of the H1row(e) matrix are generated and stored in the register unit 143. When Sₖ₋₁ is entered, the last column elements of the H1row(e) matrix are generated and stored in the register unit 143. When the last column elements of the H1row(e) matrix are stored in the register unit 143, storage of the H1row(e) matrix is completed.

Referring to equation 6 again, because

$${P}_{0}^{T} = {\sum }_{e = 0}^{m - 1} H 1 row ( e ) \cdot {s}^{T} ,$$

the following equation can be obtained.

P₀^{T}=H1row(0)·S^{T}+H1row(1)·S^{T}+ . . . +H1row(m−1)·S^{T}. eq. 7

According to equation 7, the parity generating unit 141 may obtain P₀^{T} by using the elements of the each column of the H1row(e). When P₀^{T} is obtained, P₁^{T}, . . . , Pₘ₋₁^{T} may be obtained according to equation 6. To calculate P₁^{T}, . . . , Pₘ₋₁^{T}, h₂(f) is used. Therefore, P₁^{T}, . . . , Pₘ₋₁^{T} may be calculated relatively easily because the h₂(f) has h₂(0)=1, h₂ (integer part of ‘n−k/2’)=1, h₂(n−k)=1, and other elements of the h₂(f) is zero.

When Pₘ₋₁^{T} is generated, the parity generating unit 141 may provide the codeword x=[s p] as the encoded data for the modulator 11. The modulator 11 may perform wireless-modulation of the codeword x=[s p] to transmit the codeword to the receiver 30 via the antenna 13.

FIG. 3 is a diagram illustrating He matrix when a code rate is ½.

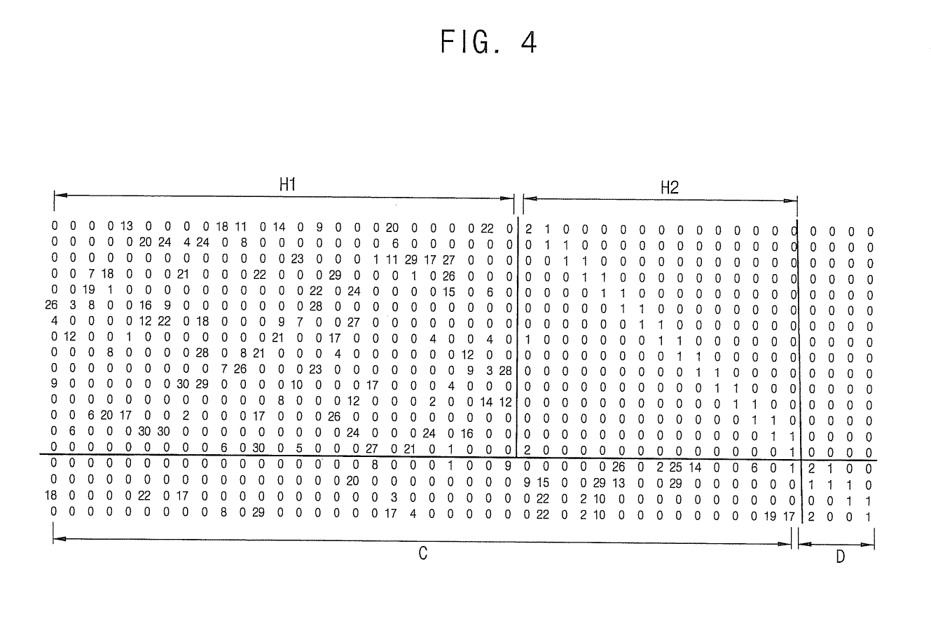

FIG. 4 is a diagram illustrating He matrix when a code rate is ⅝.

FIG. 5 is a diagram illustrating He matrix when a code rate is ¾.

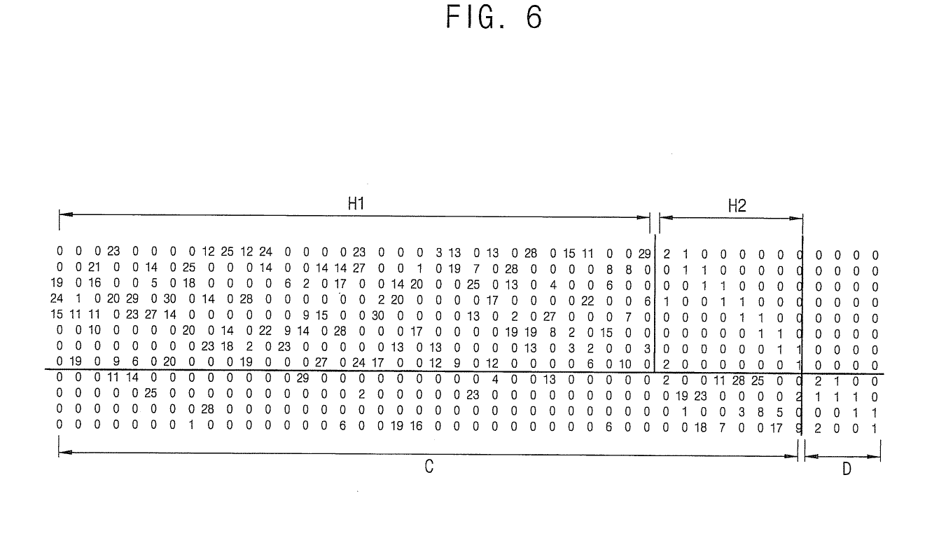

FIG. 6 is a diagram illustrating He matrix when a code rate is ⅘.

Referring FIGS. 3 to 6, the D matrices in the He matrix may be identical regardless of code rate. Therefore, the table unit 120 stores the H matrix and the C matrix, and provides the elements of the H matrix and the C matrix for the shifter unit 150, according to the control of the controller 110 with respect to the code rate.

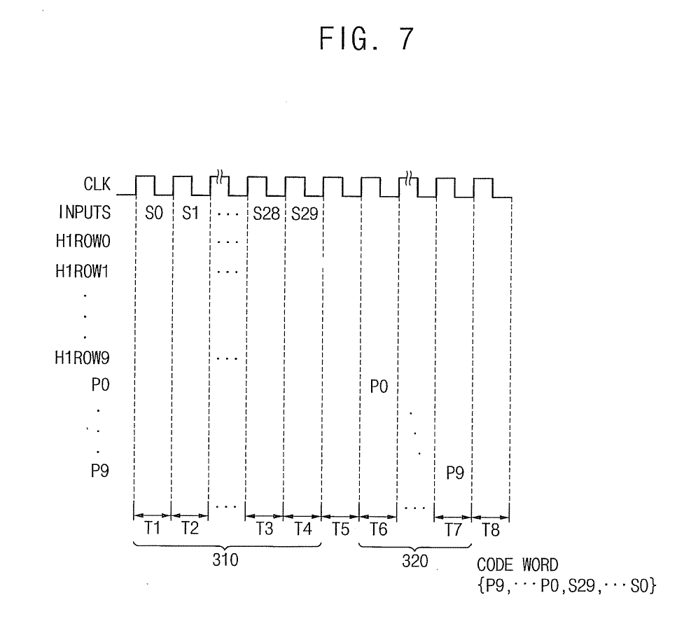

FIG. 7 is a timing diagram illustrating process of generating parity vectors according to at least one example embodiment.

FIG. 7 is a timing diagram illustrating a process of generating parity vectors, when the code rate is ¾. Referring FIG. 7, each of the input vectors S₀, S₁, . . . , S₂₉ may sequentially input at every clock CLK. S₀ is entered at time interval (T1). While S₁ is entered at time interval (T2), S₀ is cyclically shifted with a non-zero element value of the first column of the H1 matrix, columnwise to the right, in parallel. In addition, the shifted S₀ is stored in the register unit 143 as a first column element of the H1row(e) matrix. Substantially the same processes are repeated during time intervals T3 and T4. During the time interval T4, S₂₉ and the last column elements of the H1row(e) matrix are stored in the register unit 143. In other words, calculation of all elements of the H1row(e) matrix is completed one clock after S₂₉ is entered. During a time interval T6, P₀^{T} is calculated in according to equation 7, and the process is repeated to calculate P₉^{T} during the time interval T7. Therefore, from the time interval T8, the codeword x=[s p] may be provided for the modulator 11 as the encoded data.

In FIG. 7, a latency, which denotes a time interval from input of the input vectors S₀, S₁, . . . , S₂₉ (310) to generation of the parity vectors P₀, P₁, . . . , P₉, is a sum of the time interval T5 and the time interval 320. The time interval T5 denotes the time for generating the elements of the last column of the H1row(e) matrix, after input of S₂₉. The time interval 320 denotes the time for generating the parity vectors P₀, P₁, . . . , P₉. Therefore, the latency is 11 clock (CLK)-cycles when the code rate is ¾.

When the code rate is ½ as described in FIG. 3, the latency is a sum the of the time interval for generating the elements of the last column of the H1row(e) matrix (1 clock cycle) and the time for generating the parity vectors (20 clock cycles). Therefore, the latency is 21 clock cycles when the code rate is ½. Similarly, the latency is 16 clock cycles when the code rate is ⅝. Further, the latency is 9 clock cycles if the code rate is ⅘.

As described above, the corresponding elements of the H1row(e) matrix may be generated columnwise and stored in the register unit, and the parity vectors may be calculated sequentially, while the input vectors S₀, S₁, . . . , Sₖ₋₁ are received. Therefore, the amount of computations and the latency may be reduced. The circuit size and the power consumption may also be relatively reduced.

The process of generating the extended parity vectors using the H matrix and the C matrix will be described below.

The relation of xₑ=[s p pₑ] (Here, pₑ denotes the extended parity vector), equation 4 corresponds to the He and the xₑ. Therefore, equation 8 may be obtained.

He·xₑ^{T}=0^{T} eq. 8

Therefore, equation 9 (below) may be obtained by using

$$He = [ \begin{matrix}H & 0 \\ C & D\end{matrix} ]$$

and xₑ=[s p pₑ].

pₑ^{T}=D⁻¹·C·sₑ^{T} eq. 9

where, D is

$$D = [ \begin{matrix}2 & 1 & 0 & 0 \\ 1 & 1 & 1 & 0 \\ 0 & 0 & 1 & 1 \\ 2 & 0 & 0 & 1\end{matrix} ] .$$

Therefore, equation 10 (below) may be obtained by the relations pₑ={Pe₀, Pe₁, Pe₂, Pe₃} and sₑ=[s p] in equation 9.

$${P}_{e 0}^{T} = {\sum }_{e = 0}^{3} C row ( e ) \cdot {s}_{e}^{T} \\ {P}_{e 1}^{T} = C row ( 0 ) \cdot {s}_{e}^{T} + {d}_{0} \cdot {P}_{e 0}^{T} \\ {P}_{e 2}^{T} = C row ( 1 ) \cdot {s}_{e}^{T} + {d}_{1} \cdot {P}_{e 0}^{T} + {P}_{e 1}^{T} \\ {P}_{e 3}^{T} = C row ( 2 ) \cdot {s}_{e}^{T} + {d}_{1} \cdot {P}_{e 0}^{T} + {P}_{e 2}^{T} . \qquad eq . 10$$

Where, d₀, d₁, and d₂ respectively denote 2, 1, and 0, which are first, second, and third row elements of the first column of the D matrix.

Equation 11 may be obtained by equation 10.

Pₑ₀^{T}=Crow(0)·sₑ^{T}+Crow(1)·sₑ^{T}+Crow(2)·sₑ^{T}+Crow(3)·sₑ^{T}. eq. 11

Therefore, Pₑ₀ may be obtained if the Crow(e) matrix is obtained. In addition, Pₑ₁, Pₑ₂, and Pₑ₃ may be obtained from Pₑ₀. The Crow(e) matrix may include the cyclicaly shifted input vectors S₀, S₁, . . . , Sₖ₋₁ and the cyclically shifted parith vectors P₀, P₁, . . . , Pₘ₋₁ as the elements of the matrix. The input vectors S₀, S₁, . . . , Sₖ₋₁ and the parith vectors P₀, P₁, . . . , Pₘ₋₁ may be cyclically shifted with values of the non-zero elements of the corresponding column of the C matrix, to form the Crow(e) matrix.

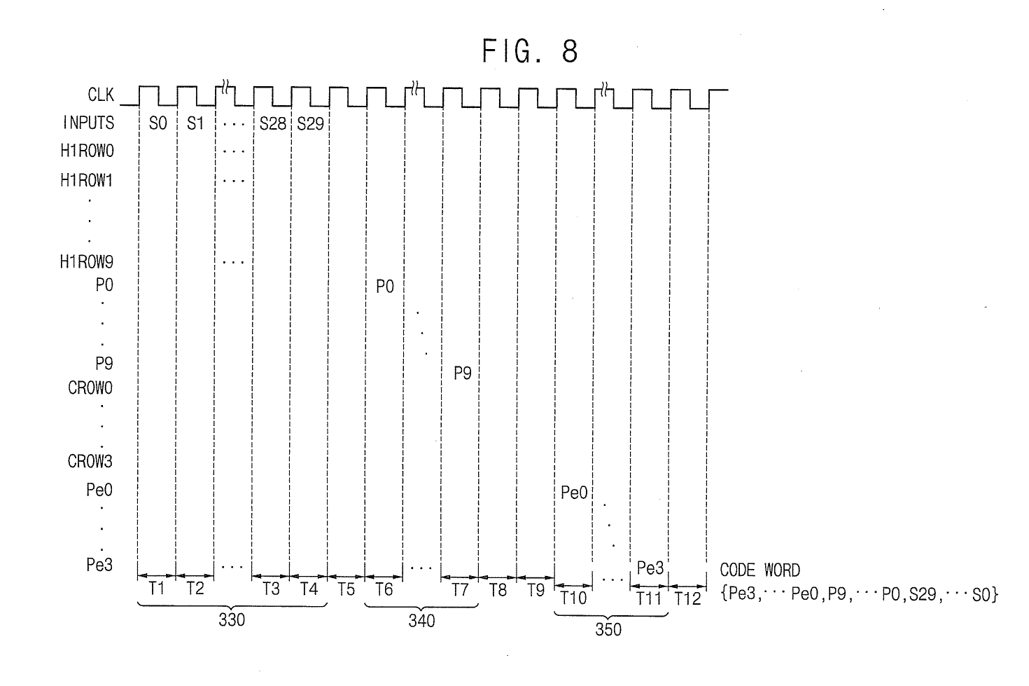

FIG. 8 is a timing diagram illustrating process of generating extended parity vectors according to example embodiments.

The process of generating the extended parity vectors will be described referring FIG. 8. The process of generating the H1row(e) matrix is described above referring to FIG. 7.

During calculation of the elements of the first column of the H1row(e) matrix, S₀ may be cyclically shifted to the right with values of the non-zero elements of the first column of the C matrix, and the shifted S₀ may be stored in the register unit 143 as the elements of the first column of the Crow(e) matrix. The same processes as described above are repeated during the time intervals T2, T3, and T4. During the time intervals T6 and T7, the parity vectors P₀, P₁, . . . , P₉ are generated sequentially. After the parity vector P₀ is generated, the parity vector P₀ may be cyclically shifted with values of the non-zero elements of the column, which may correspond to the parity vector P₀, of the C matrix. In addition, the cyclically shifted parity vector P₀ is stored in the register unit 143. The same processes are repeated until the parity vector P₉ is generated (T7). Right after the parity vector P₉ is generated (T8), the parity vector P₉ is cyclically shifted with values of the non-zero elements of the column (see FIG. 5), which may correspond to the parity vector P₉, of the C matrix. In addition, the cyclically shifted parity vector P₀ is stored in the register unit 143. Accordingly, all the elements of the Crow(e) matrix are generated at the end of the time interval T9.

During a time interval T10, the extended parity vector P₀ may be generated by using the rows of the Crow(e) matrix, according to equation 11. In addition, extended parity vector Pₑ₁ and Pₑ₂ may be generated sequentially based on the extended parity vector Pₑ₀. The extended parity vector Pₑ₃ is generated during a time interval T11. Therefore, the codeword xₑ=[s p pₑ] may be provided as the encoded data for the modulator 11, at the beginning of a time interval T12.

In FIG. 8, a latency, which denotes a time interval from input of the input vectors S₀, S₁, . . . , S₂₉ (330) to generation of the extended parity vectors Pe₀, Pe₁, Pe₂, Pe₃, may be a sum of the time interval T5, the time interval 340, the time intervals T9 and T10, and the time interval 350. The time interval T5 denotes the time for generating the elements of the last column of the H1row(e) matrix, after input of S₂₉. The time interval 350 denotes the time for generating the parity vectors P₀, P₁, . . . , P₉. The time interval 360 denotes the time for generating the extended parity vectors Pe₀, Pe₁, Pe₂, Pe₃. Therefore, the latency is 17 clock (CLK)-cycles when the code rate is ¾.

If the code rate is ½ as described in FIG. 3, the latency is the sum of the time for generating the parity vectors, the time for generating the extended parity vectors and the time of 3 clock-cycles. Therefore, the latency is 27 clock-cycles if the code rate is ½. Similarly, the latency is 22 clock-cycles if the code rate is ⅝. In addition, the latency is 15 clock-cycles if the code rate is ⅘.

As described above, the corresponding elements of the H1row(e) matrix and Crow(e) matrix may be generated columnwise and sequentially using the H matrix and the C matrix. The corresponding elements of the H1row(e) matrix and Crow(e) matrix may be stored in the register unit. Therefore, the extended parity vectors may be calculated sequentially. The amount of computations and the latency may be reduced and the circuit size and the power consumption may also be reduced.

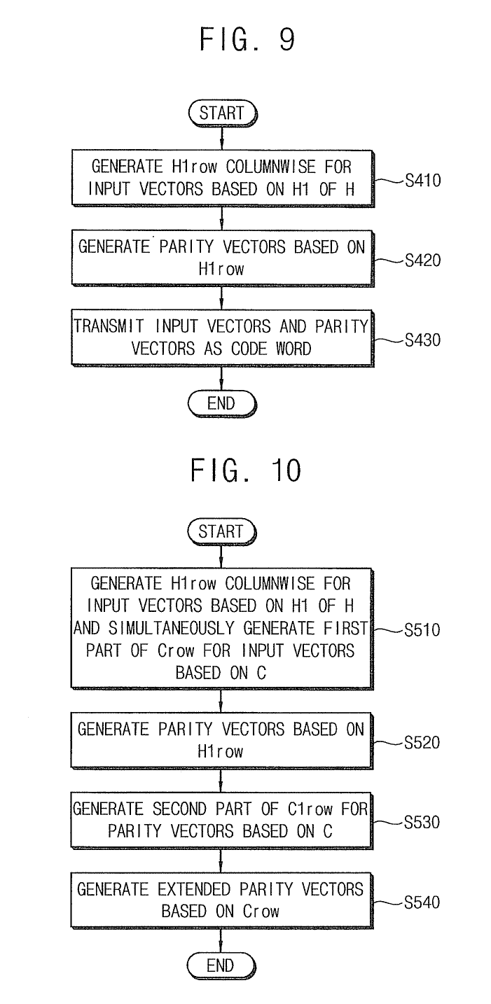

FIG. 9 is a flow chart illustrating the LDPC encoding method according to at least one example embodiment. FIG. 9 illustrates a method of generating the parity vectors using the H1 matrix.

Referring to FIG. 9, in step S410 H1row matrix is generated columnwise for each of the input vectors S₀, S₁, . . . Sₖ₋₁ based on the H1 matrix in H matrix. Based on the generated H1row matrix, in step S420, the parity vectors P₀, P₁, . . . , Pₘ are generated with respect to the input vectors S₀, S₁, . . . , Sₖ₋₁. In step S430 the input vectors S₀, S₁, . . . , Sₖ₋₁ and the parity vectors P₀, P₁, . . . , Pₘ are transmitted as the codeword. Because the LDPC encoding method of FIG. 9 is almost identical to the LDPC encoding method described referring FIG. 7, the LDPC encoding method of FIG. 9 will be omitted in the interest of brevity.

FIG. 10 is a flow chart illustrating the LDPC encoding method according to at least one example embodiment. FIG. 9 illustrates a method of generating the extended parity vectors using the H matrix and the C matrix.

Referring to FIG. 10, in step S510, the H1row matrix is generated columnwise for each of the input vectors S₀, S₁, . . . , Sₖ₋₁ based on the H1 matrix of the H matrix. For each of the input vectors S₀, S₁, . . . , Sₖ₋₁, a first part of the Crow matrix is generated columnwise based on the C matrix simultaneously. The first part of the C matrix is associated with the input vectors S₀, S₁, . . . , Sₖ₋₁ of the Crow matrix. Based on the H1row matrix, in step S520, the parity vectors P₀, P₁, . . . , Pₘ are generated with respect to the input vectors S₀, S₁, . . . , Sₖ₋₁. In step S530, a second part of the C1row matrix is generated for the parity vectors based on the C matrix. The second part of the Crow matrix is associated with the parity vectors P₀, P₁, . . . , Pₘ of the Crow matrix. In step S540, the extended parity vectors Pe₀, Pe₁, Pe₂, Pe₃ are generated based on the Crow matrix (step S540). Because the LDPC encoding method of FIG. 10 is substantially similarly to the LDPC encoding method with reference to FIG. 8, detailed description of the LDPC encoding method of FIG. 10 will be omitted for the sake of brevity.

According to example embodiments, calculation amounts and latency for generating parity vectors may be reduced. Therefore, example embodiments may be employed in a communication system which processes large amounts of data.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of example embodiments of the inventive concepts as defined in the claims. Therefor; it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

While example embodiments have been particularly shown and described, it will be understood by one of ordinary skill in the art that variations in form and detail may be made therein without departing from the spirit and scope of the claims.

What is claimed is:

1. A low density parity check (LDPC) encoding method, the method comprising:
generating a H matrix, the H matrix including a H1 matrix and a H2 matrix,
generating a He matrix based on a ratio of the H matrix and a zero matrix to a C matrix and a D matrix,
generating a H1row matrix columnwise for each of a plurality of input vectors based on the H1 matrix; and
generating parity vectors for each of the plurality of input vectors based on the H1row matrix.

2. The LDPC encoding method of claim 1, wherein the H1row matrix is generated by shifting cyclically each of the input vectors by each of element values of the corresponding column of the H1 matrix.

3. The LDPC encoding method of claim 1, wherein each of column elements of the H1row matrix is generated in parallel, the column elements being associated with the plurality of input vectors.

4. The LDPC encoding method of claim 1, wherein the parity vectors are generated sequentially after calculating all of the columns of the H1row matrix.

5. The LDPC encoding method of claim 1, further comprising:
transmitting the generated parity vectors and the input vectors as codewords.

6. The LDPC encoding method of claim 1, further comprising:
generating a first part of a Crow matrix for each of the input vectors based on the C matrix, simultaneously with the generation of the H1row matrix;
generating a second part of the Crow matrix for each of the input vectors based on the C matrix; and
generating extended parity vectors based on the Crow matrix.

7. The method of claim 1, wherein
if a code rate is ½, the code rate being a ratio of each length of the input vectors to each length of a plurality of code words, the plurality of code words including the input vectors and the parity vectors,
the H1 matrix is [0 0 0 0 21 0 0 24 0 1 0 0 0 0 0 0 0 4 0 0; 0 0 20 19 0 18 0 0 0 0 0 0 0 14 0 0 0 0 0 0; 0 0 0 0 23 14 20 0 0 0 0 0 0 0 0 0 0 0 13 0; 4 0 0 0 0 0 0 14 0 0 0 0 0 0 0 0 29 17 0 0; 0 0 4 11 0 0 0 0 2 0 0 0 0 12 0 0 0 0 0 0; 0 0 0 0 9 0 0 0 0 0 0 0 0 0 0 11 0 11 14 0; 0 0 0 0 0 0 0 0 0 13 0 14 0 7 0 0 20 0 0 0; 0 0 0 0 6 0 28 0 9 0 0 25 0 0 0 0 0 0 0 0; 0 0 0 0 0 24 0 0 0 0 0 0 0 0 0 15 0 0 15 23; 0 3 0 0 0 0 16 29 0 0 0 0 0 0 0 0 0 0 0 0; 0 0 0 14 0 0 0 0 18 0 0 0 0 0 0 0 0 0 0 19; 0 0 0 0 0 0 0 0 0 2 0 0 2 2 21 0 0 0 0 0; 0 7 0 0 0 0 0 0 0 0 0 1 23 0 0 0 22 0 0 0; 0 0 0 0 0 0 0 0 0 0 0 26 26 0 11 0 0 0 0 4; 8 0 11 0 0 0 0 0 0 0 0 0 0 0 0 8 0 0 0 0; 0 20 5 3 0 0 0 0 0 0 0 0 0 0 0 0 0 0 0 18; 15 0 0 0 0 0 0 0 27 0 17 0 0 0 17 0 0 0 0 0; 0 0 0 0 0 4 0 0 0 18 25 0 0 0 0 0 0 0 0 22 0; 0 24 0 0 0 0 0 0 0 0 0 0 16 0 16 0 0 0 0 0; 0 0 0 0 0 0 0 7 0 0 20 0 0 0 0 26 0 5 0 0],
the second matrix is [h₂(f)|H2′] where,
h₂(f) is a first column of the H2 matrix, f is an integer value from 0 to 19 such that h₂(0) is 2, h₂(9) is 1, and h₂(19) is 2, and
H2′ is a matrix having a dual diagonal structure such that elements of the H2′ matrix are 1 if i=j, or j=i+1, and are 0 otherwise, i is a row index of the H2′ matrix (i is from 0 to 19) and j is a column index of the H2′ matrix (j is from 1 to 19)),
the C matrix is [0 0 0 0 0 0 13 0 0 0 0 20 0 0 0 0 1 0 0 0 0 0 0 0 0 0 0 21 0 0 0 0 0 0 0 0 0 0 0 0; 0 0 0 0 0 0 0 0 0 12 0 0 0 0 0 0 0 0 0 10 0 0 0 19 0 0 0 0 0 0 0 0 0 0 0 0 0 0 0 0; 0 0 2 0 0 0 0 0 0 0 0 0 0 0 0 3 0 0 0 0 5 0 0 0 0 10 0 0 0 0 0 0 0 0 0 0 0 0 0 0; 19 0 0 0 0 0 0 0 16 0 0 0 26 0 3 0 0 0 0 0 0 0 0 0 0 0 0 0 0 0 0 0 0 0 0 0 0 0 0 0], and
the D matrix is [2 1 0 0; 1 1 1 0; 0 0 1 1; 2 0 0 1].

8. The method of claim 1, wherein
if a code rate is ⅝, the code rate being a ratio of each length of the input vectors to each length of a plurality of code words, the plurality of code words including the input vectors and the parity vectors,
the H1 matrix is [0 0 0 0 13 0 0 0 0 18 11 0 14 0 9 0 0 0 20 0 0 0 0 22 0; 0 0 0 0 0 20 24 4 24 0 8 0 0 0 0 0 0 0 6 0 0 0 0 0 0; 0 0 0 0 0 0 0 0 0 0 0 0 0 23 0 0 0 1 11 29 17 27 0 0 0; 0 0 7 18 0 0 0 21 0 0 0 22 0 0 0 29 0 0 0 1 0 26 0 0 0; 0 0 19 1 0 0 0 0 0 0 0 0 0 0 22 0 24 0 0 0 0 0 15 0 6; 26 3 8 0 0 16 9 0 0 0 0 0 0 0 28 0 0 0 0 0 0 0 0 0 0; 4 0 0 0 0 12 22 0 18 0 0 0 9 7 0 0 27 0 0 0 0 0 0 0 0; 0 12 0 0 1 0 0 0 0 0 0 0 21 0 0 17 0 0 0 0 4 0 0 4 0; 0 0 0 8 0 0 0 0 28 0 8 21 0 0 0 4 0 0 0 0 0 0 12 0 0; 0 0 0 0 0 0 0 0 0 7 26 0 0 0 23 0 0 0 0 0 0 0 9 3 28; 9 0 0 0 0 0 0 30 29 0 0 0 0 10 0 0 0 17 0 0 0 4 0 0 0; 0 0 0 0 8 0 0 0 0 0 0 0 8 0 0 0 12 0 0 0 2 0 0 14 12; 0 0 6 20 17 0 0 2 0 0 0 17 0 0 0 26 0 0 0 0 0 0 0 0 0; 0 6 0 0 0 30 30 0 0 0 0 0 0 0 0 0 24 0 0 0 24 0 16 0 0; 0 0 0 0 0 0 0 0 0 6 0 30 0 5 0 0 0 27 0 21 0 1 0 0 0];
the H2 matrix is [h₂(f)|H2′], where
h₂(f) is a first column of the H2 matrix, f is an integer value from 0 to 14 such that h₂(0) is 2, h₂(7) is 1, and h₂(14) is 2, and
H2′ is a matrix having a dual diagonal structure such that elements of the H2′ matrix are 1's if i=j, or j=i+1, and are 0 otherwise, i is a row index of the H2′ matrix (i is from 0 to 14), and j is a column index of the H2′ matrix (j is from 1 to 14)),
the C matrix is [0 0 0 0 0 0 0 0 0 0 0 0 0 0 0 0 0 8 0 0 0 0 0 0 9 0 0 0 0 0 26 0 2 25 14 0 0 6 0 0; 0 0 0 0 0 0 0 0 0 0 0 0 0 0 0 0 20 0 0 0 0 0 0 0 0 9 15 0 0 29 13 0 0 29 0 0 0 0 0 0; 18 0 0 0 0 22 0 17 0 0 0 0 0 0 0 0 0 0 22 0 2 10 0 0 0 0 0 0 0 0 0 0; 0 0 0 0 0 0 0 0 0 8 0 29 0 0 0 0 0 0 17 4 0 0 0 0 0 0 0 0 0 0 0 0 0 0 0 0 0 0 19 17], and
the D matrix is [2 1 0 0; 1 1 1 0; 0 0 1 1; 2 0 0 1].

9. The method of claim 1, wherein
if a code rate is ¾, the code rate being a ratio of each length of the input vectors to each length of a plurality of code words, the plurality of code word including the input vectors and the parity vectors,
the H1 matrix is [2 0 0 0 0 0 0 0 0 29 6 0 0 0 0 0 28 3 28 8 0 0 0 12 20 0 0 0 20; 7 0 0 0 7 9 0 16 0 5 0 0 24 0 0 0 0 17 0 0 0 27 0 0 0 0 0 0 8 3; 0 22 0 23 11 22 0 0 25 12 0 0 0 0 0 0 21 0 0 0 0 0 0 0 0 0 16 2 22 0; 0 25 7 0 0 0 1 0 14 0 0 0 0 0 27 16 23 0 27 0 0 0 0 27 0 30 0 0 0 0; 0 19 0 3 0 12 0 0 30 0 0 0 0 0 0 28 0 0 28 0 0 0 28 0 0 22 0 0 0 29; 0 0 9 0 0 0 0 4 0 0 0 0 22 21 4 9 29 0 0 0 0 0 7 14 0 0 0 15 0 0; 24 0 0 0 0 0 0 0 0 0 12 25 28 29 30 0 0 0 0 18 20 13 0 11 0 0 0 0 0 0; 0 29 0 0 0 4 6 0 25 6 0 0 0 0 0 0 0 0 0 11 0 29 0 0 5 0 12 0 7 0; 0 0 28 0 0 0 28 0 0 0 10 0 0 28 0 0 10 0 0 14 2 0 0 0 22 0 14 8 0 0; 0 0 0 7 19 0 0 22 0 0 6 4 0 0 0 0 0 7 0 0 5 0 20 0 0 0 0 5 0 8];
the H2 matrix is [h₂(f)|H2′], where
h₂(f) is a first column of the H2 matrix, f is an integer value from 0 to 9 such that h₂(0) is 2, h₂(4) is 1, and h₂(9) is 2, and
H2′ is a matrix having a dual diagonal structure such that elements of the H2′ matrix are 1's if i=j, or j=i+1, and are 0 otherwise, i is a row index of the H2′ matrix (i is from 0 to 9), and j is a column index of the H2′ matrix (j is from 1 to 9),
the C matrix is [0 0 0 9 0 0 0 0 0 0 0 27 0 0 12 0 0 0 0 0 0 0 21 0 0 0 0 0 0 0 0 0 0 14 0 0 17 22 0 0; 27 0 0 0 0 0 0 0 0 0 0 0 15 21 0 0 0 0 18 0 0 0 0 0 0 24 0 0 0 0 0 18 12 0 0 11 0 0 0 0; 0 0 0 0 0 0 20 0 0 0 0 0 0 0 0 0 0 0 0 0 0 0 0 0 0 0 0 0 0 0 0 0 4 26 30 0 0 0 0 17; 0 0 0 0 8 0 0 0 0 1 0 0 0 0 0 0 0 11 0 0 0 0 0 0 12 0 0 0 13 0 0 0 0 0 0 0 0 0 12 0], and
the D matrix is D=[2 1 0 0; 1 1 1 0; 0 0 1 1; 2 0 0 1].

10. The method of claim 1, wherein
if a code rate is ⅘, the code rate being a ratio of each length of the input vectors to each length of a plurality of code words, the plurality of code word including the input vectors and the parity vectors,
the H1 matrix is [0 0 0 23 0 0 0 0 12 25 12 24 0 0 0 0 23 0 0 0 3 13 0 13 0 28 0 15 11 0 0 29; 0 0 21 0 0 14 0 25 0 0 0 14 0 0 14 14 27 0 0 1 0 19 7 0 28 0 0 0 0 8 8 0; 19 0 16 0 0 5 0 18 0 0 0 0 62 0 17 0 0 14 20 0 0 25 0 13 0 4 0 0 6 0 0; 24 1 0 20 29 0 30 0 14 0 28 0 0 0 0 0 0 2 20 0 0 0 0 17 0 0 0 0 22 0 0 6; 15 11 11 0 23 27 14 0 0 0 0 0 0 9 15 0 0 30 0 0 0 0 13 0 2 0 27 0 0 0 7 0; 0 0 10 0 0 0 0 20 0 14 0 22 9 14 0 28 0 0 0 17 0 0 0 0 19 19 8 2 0 15 0 0; 0 0 0 0 0 0 0 0 23 18 2 0 23 0 0 0 0 0 13 0 13 0 0 0 0 13 0 3 2 0 0 3; 0 19 0 9 6 0 20 0 0 0 19 0 0 0 27 0 24 17 0 0 12 9 0 12 0 0 0 0 6 0 10 0];
the H2 matrix is [h₂(f)|H2′], where
h₂(f) is a first column of the H2 matrix, is an integer value from 0 to 7 such that h₂(0) is 2, h₂(3) is 1, and h₂(7) is 2, and
H2′ is a matrix having a dual diagonal structure such that elements of the H2′ matrix are 1's if i=j, or j=i+1, and are 0 otherwise, i is a row index of the H2′ matrix (i is from 0 to 7), and j is a column index of the H2′ matrix (j is from 1 to 7));
the C matrix is C=[0 0 0 11 14 0 0 0 0 0 0 0 0 29 0 0 0 0 0 0 0 0 0 4 0 0 13 0 0 0 0 0 2 0 0 11 28 25 0 0; 0 0 0 0 0 25 0 0 0 0 0 0 0 0 0 0 2 0 0 0 0 0 23 0 0 0 0 0 0 0 0 0 0 19 23 0 0 0 0 2; 0 0 0 0 0 0 0 0 28 0 0 0 0 0 0 0 0 0 0 0 0 0 0 0 0 0 0 0 0 0 0 0 0 1 0 0 3 8 5 0; 0 0 0 0 0 0 0 1 0 0 0 0 0 0 0 6 0 0 19 16 0 0 0 0 0 0 0 0 0 6 0 0 0 0 18 7 0 0 17 9], and
the D matrix is [2 1 0 0; 1 1 1 0; 0 0 1 1; 2 0 0 1].

11. A low density parity check (LDPC) encoder, comprising:
a table unit configured to store a H matrix and a He matrix, the H matrix including a first H1 matrix and a second H2 matrix, and the He matrix based on a ratio of the H matrix and a zero matrix to a C matrix and a D matrix;
an arithmetic unit configured to generate a H1row matrix columnwise for each of a plurality of input vectors based on the H1 matrix, and configured to generate parity vectors for each of the plurality of input vectors based on the H1row matrix; and
a controller configured to control the table unit and the arithmetic unit.

12. The LDPC encoder of claim 11, wherein the controller comprises:
one or more barrel shifters configured to generate the H1row matrix by shifting cyclically each of the input vectors by each of element values of the corresponding column of the H1 matrix; and
a parity generating unit configured to store the generated H1 row matrix, and configured to generate the parity vectors based on the H1row matrix.

13. The LDPC encoder of claim 12, wherein the barrel shifters generate each of column elements of the H1row matrix in parallel, the column elements being associated with the plurality of input vectors.

14. The LDPC encoder of claim 11, wherein the LDPC encoder generates Crow matrix columnwise for each of the input vectors and for the parity vectors based on the C matrix, and further generates extended parity vectors based on the generated Crow matrix.

15. A wireless communication system, comprising:
a transmitter including the LDPC encoder of claim 11.

16. A low density parity check (LDPC) encoding method, the method comprising:
shifting each of a plurality of input vectors by each value of an element of a corresponding column of a first matrix; and
generating parity vectors for each of the plurality of input vectors based on the shifted input vectors.

17. The LDPC encoding method of claim 16, further comprising:
transmitting the generated parity vectors and the input vectors as a plurality of code words.

18. The LDPC encoding method of claim 17, wherein
a variable code rate of transmission data is based on a ratio of a length of the input vectors to a length of each of the plurality of codewords, and
the variable code rate of transmission data varies based on matrices associated with a second matrix.

19. The LDPC encoding method of claim 16, further comprising:
generating a first part of a row matrix for each of the input vectors based on a second matrix;
generating a second part of the row matrix for each of the input vectors based on the second matrix; and
generating extended parity vectors based on the row matrix, wherein the first part of the row matrix is generated in parallel with the shifting of each of the plurality of input vectors.
